(19) United States
(12) Patent Application Publication
(10) Pub. No.: US 2014/0216514 A1
(43) Pub. Date: Aug. 7, 2014

(54) THERMOELECTRIC MODULE AND DEVICE, PARTICULARLY FOR GENERATING AN ELECTRIC CURRENT IN A MOTOR VEHICLE

(71) Applicant: Michel Simonin, Voisins Le Bretonneux (FR)

(72) Inventor: Michel Simonin, Voisins Le Bretonneux (FR)

(73) Assignee: VALEO SYSTEMS THERMIQUES, Le Mesnil Saint Denis (FR)

(21) Appl. No.: 14/122,974

(22) PCT Filed: May 29, 2012
(86) PCT No.: PCT/EP2012/060052

§ 371 Date: Apr. 8, 2014

(30) Foreign Application Priority Data
Jun. 1, 2011 (FR) 1154838

(51) Int. Cl. H01L 35/30

(52) U.S. Cl. CPC H01L 35/30
USPC 136/205

(57) ABSTRACT

The invention relates to a thermoelectric module including at least one thermoelectric element (3, 3p, 3n) which is capable of generating an electric current by means of a temperature gradient applied between two of the surfaces thereof, one so-called first surface (4a) from among said surfaces having an area that is greater than that of the other so-called second surface (4b), said module being configured to establish an exchange of heat between said first surface (4a) and a first fluid, and to establish an exchange of heat between said second surface (4b) and a second fluid, said second fluid having a heat-exchange coefficient that is greater than that of said first fluid. The invention further relates to a thermoelectric device including such a module.

The present invention relates to a thermoelectric module and device which are in particular intended to generate an electric current in a motor vehicle.

In the automobile field thermoelectric devices have already been proposed using elements, so-called thermo electrical elements, making it possible to generate an electric current in the presence of a temperature gradient between two of their opposing faces according to the known phenomenon under the name of the Seebeck effect. These devices comprise a stack of first tubes intended for the circulation of exhaust gases from an engine, and of second tubes intended for the circulation of a heat transfer fluid from a cooling circuit. The thermoelectric elements are sandwiched between the tubes in such a way as to be subjected to a temperature gradient originating from the temperature difference between the hot exhaust gases and the cold cooling fluid.

Such devices are particularly interesting since they make it possible to produce electricity on the basis of a conversion of the heat originating from the exhaust gases of the engine. Thus they offer the possibility of reducing the fuel consumption of the vehicle by being substituted, at least partially, for the alternator usually provided in this latter in order to generate electricity on the basis of a belt driven by the crankshaft of the engine.

The known thermoelectric elements are in the shape of a parallelepipedal rectangle and the temperature gradient making it possible to generate the expected electrical current is imposed between two of their opposing faces. These are therefore faces of the same dimensions.

The coefficients of heat exchange by convection between a fluid and the wall of a tube in the case respectively of a liquid and a gas are very different. The thermal efficiency of the assembly is thus limited by the fluid, in this case the exhaust gases, having the lowest heat exchange coefficient.

A first solution in order to solve this problem is to increase the gas-side exchange surfaces. However, such a solution has limits since, as the devices are installed on the exhaust path of the vehicle, they absolutely must have a resistance to the flow of gases which is as low as possible in order to limit the effect of counter-pressure due, either to the definition of the exchange surfaces placed in the tube or to the effect of fouling by deposition of soot contained in the gases, which would be prejudicial to the effective functioning not only of the thermoelectric device but also of the engine. These constraints therefore limit the possibility of substantially increasing the exchange coefficient by high-performance exchange surfaces.

Thus the gas-side exchange coefficients are lower than the liquid-side exchange coefficients by a value which may exceed ten. As the exchange surfaces are identical, the ratio between the gas-side thermal resistance and the liquid-side thermal resistance is the inverse of the ratio between the gas-side thermal exchange coefficient and the liquid-side exchange coefficient. Thus the gas-side thermal resistance is much greater than the liquid-side thermal resistance which has an adverse effect on the performance of the device.

The invention proposes to improve the situation and to this end relates to a thermoelectric module comprising at least one thermoelectric element which is capable of generating an electric current under the action of a temperature gradient exerted between two of its faces, one, so-called first, of said faces having a greater surface area than the other, so-called second face, said module being configured in order to establish a heat exchange between said first face and a first fluid and to establish a heat exchange between said second face and a second fluid, said second fluid having a higher thermal exchange coefficient than said first fluid.

Thus, using a greater exchange surface on the fluid having the lower exchange coefficient it is possible to have a more balanced ratio between the gas-side thermal resistance and the liquid-side thermal resistance, which favours the operation of the whole assembly.

According to different aspects of the invention, which could be taken together or separately:
the thermoelectric element is in the form of a ring or portion of a ring, the first surface is defined by an external peripheral surface of the ring and the second surface is defined by an internal peripheral surface of the ring,
said first and/or second surfaces are generated by a straight line,
said first and/or second surfaces are of cylindrical shape,
the first surface has a radius between 1.5 and 4 times the radius of the second surface,
said first and/or second surfaces are coaxial,
said thermoelectric element has two opposing parallel planar faces,
the module comprises a plurality of said thermoelectric elements,
said thermoelectric elements are of two types, a first type, referred to as P, which makes it possible to establish an electrical potential difference between said first and second faces when they are subjected to a given temperature gradient, and a second type, referred to as N, which makes it possible to create an electrical potential difference in an opposite direction between said first and second faces when they are subjected to the same temperature gradient,
said thermoelectric elements are each disposed in the longitudinal extension of the other and the thermoelectric elements of type P alternate with the thermoelectric elements of type N,
the thermoelectric elements are grouped in pairs formed by a said thermoelectric element of type P and by a said thermoelectric element of type N, said module being configured in order to enable a circulation of current between the first surfaces of the thermoelectric elements of one and the same pair and a circulation of current between the second surfaces of each of the thermoelectric elements of the same pair and the adjacent thermoelectric element of the adjacent pair,
said thermoelectric elements are disposed relative to one another in such a way that their first and/or second surfaces are each in the extension of the other,
said thermoelectric elements are of identical shape and dimensions,
said first and/or second surfaces are inscribed in a surface generated by a straight line,
the module comprises a cold liquid circulation channel in contact with said second surface of said thermoelectric elements and/or a gas circulation channel in contact with said first surface of said thermoelectric elements,
said cold liquid circulation channel(s) is (are) circular and the gas circulation channel is annular, said thermoelectric elements being disposed radially between said cold liquid circulation channel(s) on the one hand and the gas circulation channel on the other hand,
the channel for circulation of gas is provided with secondary exchange surfaces,
the module comprises an external insulating casing, in particular a casing which enables thermal insulation between exhaust gases and the ambient air,
said external casing defines an external wall of the gas circulation channel.

According to one embodiment, the module comprises a plurality of tubes each positioned in the axial extension of the other in such a way as to define said cold fluid circulation channel and/or a plurality of tubes each positioned in the axial extension of the other so as to be able to define successive portions of an internal wall of said gas circulation channel.

According to this embodiment, the device may exhibit the following characteristics:
sealing joints are provided between said successive cold liquid circulation tubes and/or between said successive gas circulation tubes, also ensuring electrical insulation respectively between said cold liquid circulation tubes and/or between said gas circulation tubes,
the cold liquid circulation tubes and/or gas circulation tubes are provided with shoulders against which the thermoelectric elements and/or the sealing joints are supported.

According to another alternative embodiment, the module comprises a cold liquid circulation tube on which are mounted at least two thermoelectric elements of the same type alternating along the direction of longitudinal extension with a thermoelectric element of the other type. According to this embodiment, the device may exhibit the following characteristics:
the thermoelectric elements are coated with a layer of electrically insulating and thermally conductive material at least partially defining an internal wall of the gas circulation channel,
the secondary exchange surface is configured to ensure the retention of the thermoelectric elements.

According to the invention, the module may likewise comprise a plurality of cold liquid circulation channels, in particular parallel to one another, each channel co-operating with a plurality of thermoelectric elements each forming an angular cylinder section and each positioned in the extension of the other along the longitudinal direction of extension of the corresponding channel.

The invention likewise relates to a thermoelectric device comprising a plurality of modules such as are described above.

According to different aspects of the invention, which could be taken together or separately:
said device comprises a body having a plurality of recesses which house said modules,
said body is made from refractory, insulating and/or cellular material,
said modules are retained in said recesses by the secondary exchange surfaces,
said recesses are disposed in such a way that the gas circulation channels of the different modules are parallel to one another,
the device comprises a gas circulation channel bypassing said modules,
said body is covered with an external shock-absorbing casing.

The invention will be better understood in the light of the following description which is given only by way of illustration and not for the purpose of limitation, accompanied by the appended drawings in which:

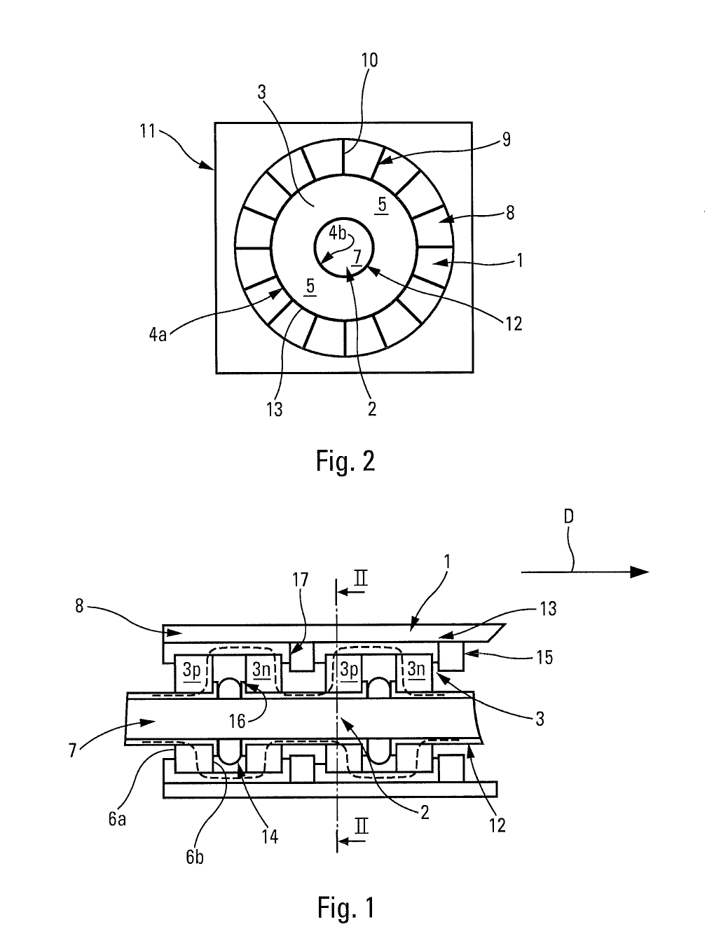

FIG. 1 illustrates schematically, along an axial sectional plane, a first embodiment of a module according to the invention,

FIG. 2 shows a sectional view along the line II-II in FIG. 1, illustrating a portion of said first embodiment of a module according to the invention,

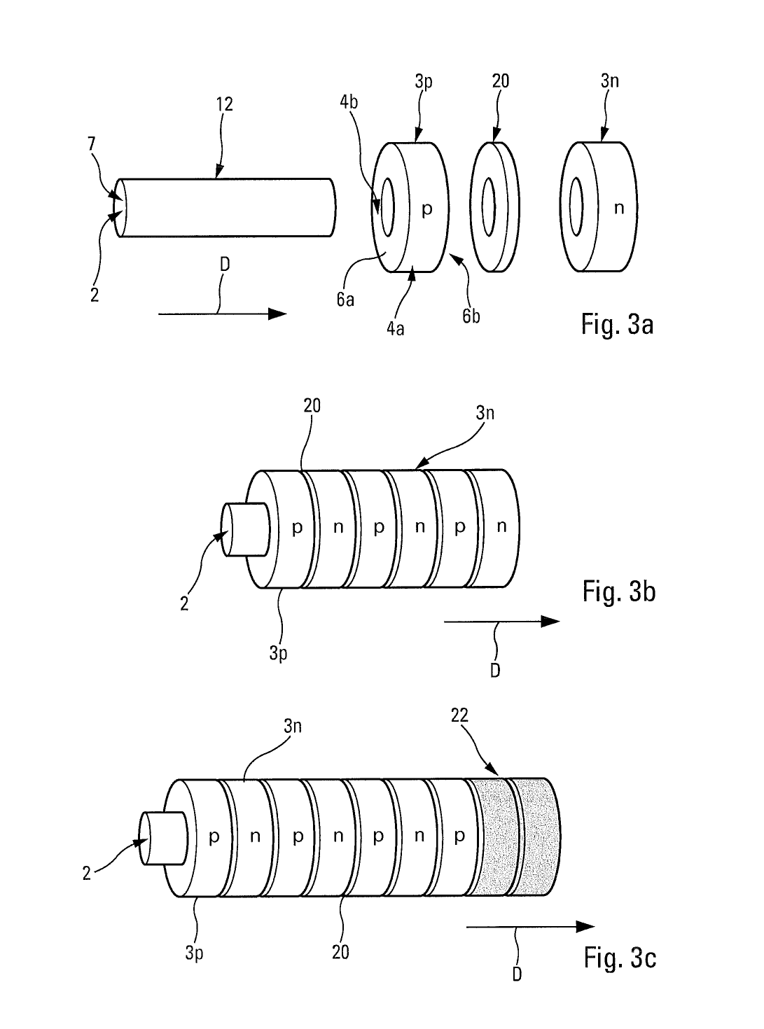

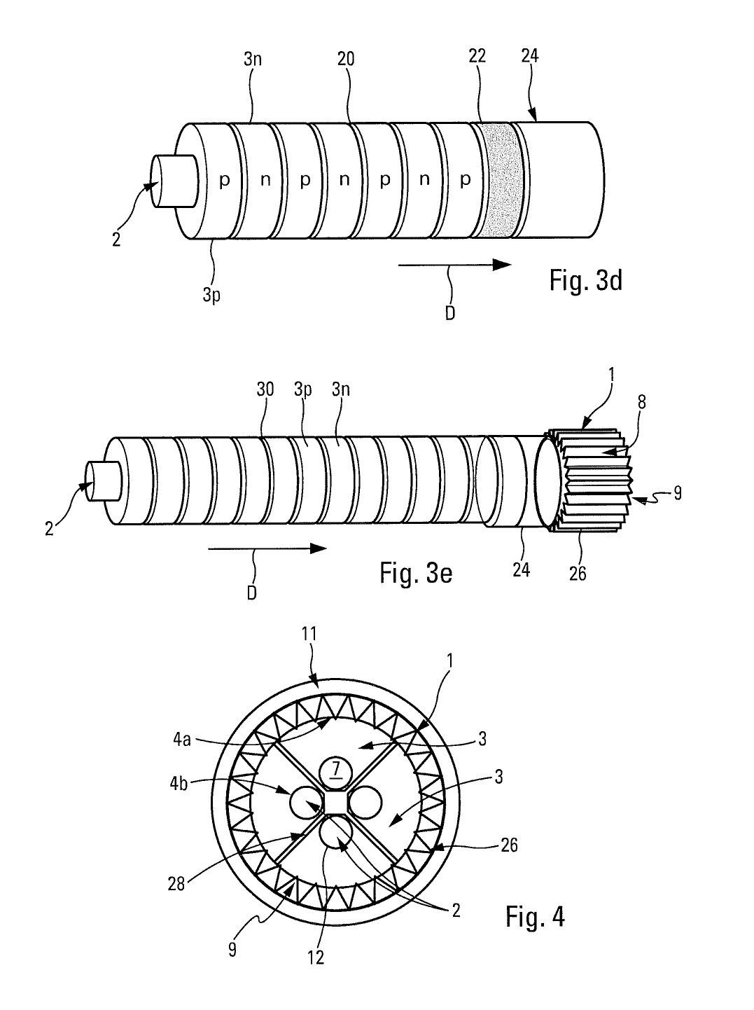

FIGS. 3a to 3e illustrate schematically, in perspective, the different steps of mounting of a second embodiment of a module according to the invention,

FIG. 4 illustrates schematically, along a diametral sectional plane, another embodiment of a module according to the invention,

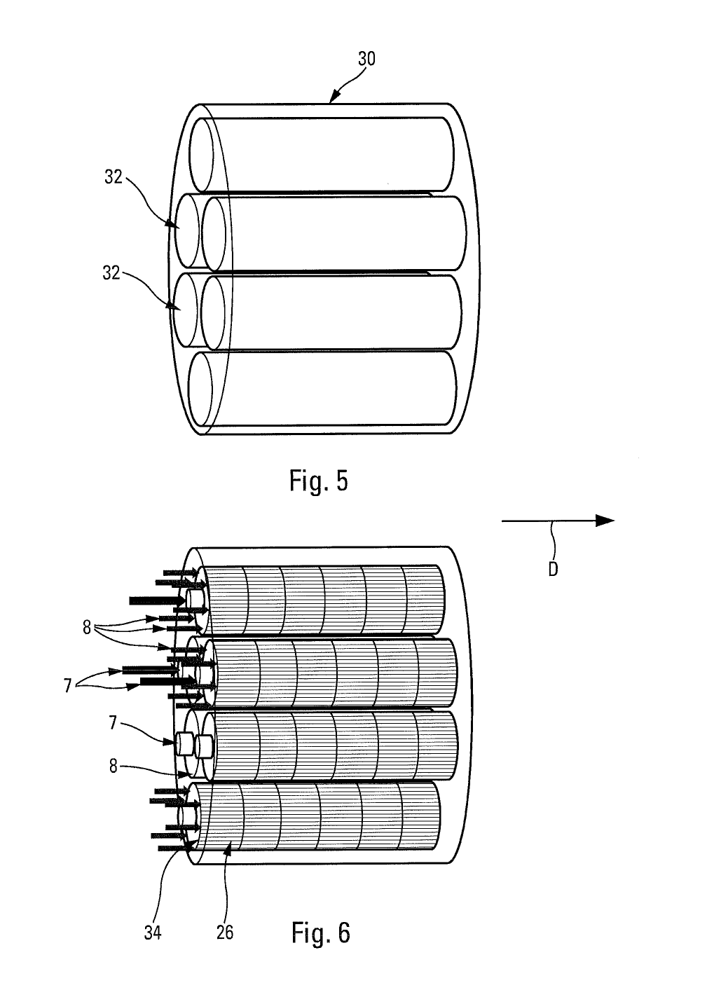

FIG. 5 illustrates schematically, in perspective, the body of an embodiment according to the invention,

FIG. 6 illustrates an embodiment according to the invention equipped with the body shown in FIG. 5,

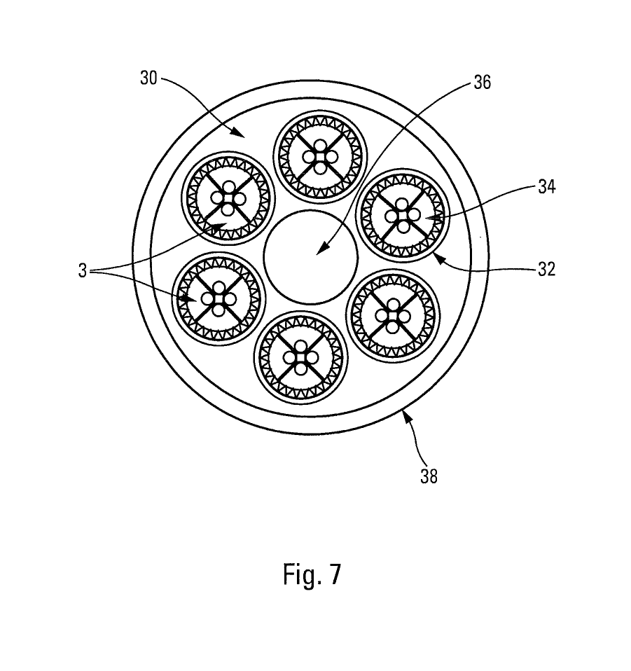

FIG. 7 illustrates schematically, along a diametral sectional plane, a variant of the embodiment according to the invention.

As illustrated in FIGS. 1 to 4, the invention relates to a thermoelectric module, comprising a first circuit 1, referred to as hot, capable of enabling the circulation of a first fluid, in particular exhaust gases from a motor, and a second circuit 2, referred to as cold, capable of enabling the circulation of a second fluid, in particular a heat transfer fluid of a cooling circuit, with a temperature lower than that of the first fluid.

The module also comprises a plurality of thermoelectric elements 3, 3p, 3n, capable of generating an electrical current under the action of a temperature gradient exerted between two of their faces 4a, 4b. Such elements function according to the Seebeck effect by making it possible to create an electrical current in a load connected between said faces 4a, 4b subjected to the temperature gradient. In a manner which is known to the person skilled in the art, such elements are composed for example of bismuth and tellurium (Bi₂Te₃).

The thermoelectric elements are, on the one hand, elements 3p of a first type, referred to as P, which make it possible to establish an electrical potential difference in one direction, referred to as positive, when they are subjected to a given temperature gradient, and, on the other hand, elements 3n of a second type, referred to as N, which make it possible to create an electrical potential difference in an opposite direction, referred to as negative, when they are subjected to the same temperature gradient.

According to the invention, one 4a, referred to as the first, of said faces has a greater surface area than the other 4b, referred to as the second face, and said module is configured in order to establish a heat exchange between said first face and the first fluid and to establish a heat exchange between said second face and the second fluid, said second fluid having a higher thermal exchange coefficient than said first fluid.

This favours the exchange between the thermoelectric elements 3p, 3n, and the fluid having the lowest thermal exchange coefficient, in this case the exhaust gases.

An example of a thermoelectric element with which the module according to the invention is equipped is described below.

The first and/or second surfaces thereof 4a, 4b are for example generated by a straight line. This will facilitate the configuration of fluid circuits 1, 2. Thus they are in particular of cylindrical shape.

In this way it is possible to use a thermoelectric element in the form of a ring or portion of a ring, the first surface 4a being defined by an external peripheral surface of the ring whilst the second surface 4b is defined by an internal peripheral surface of the ring,

In FIG. 2, the thermoelectric element 3 shown consists of a ring formed by two identical half-rings 5 and disposed symmetrically with respect to one another. In FIGS. 3a to 3f, it is a ring in one single piece.

The first surface 4a has for example a radius between 1.5 and 4 times the radius of the second surface 4b. This radius may be equal to about 2 times that of the second surface 4b.

In order to facilitate the homogeneity of the heat exchange angularly along the thermoelectric element, said first and/or second surfaces 4a, 4b are for example coaxial. In other words, the thermoelectric element is provided with a constant radial thickness.

Said thermoelectric element has for example two opposing parallel planar faces 6a, 6b. In other words, the ring constituting the thermoelectric element is of rectangular ring section.

The combination of the thermoelectric elements with one another in the module according to the invention is described below.

Said thermoelectric elements 3p, 3n are each disposed for example in the longitudinal extension of the other, in particular coaxially, and the thermoelectric elements of type P alternate with the thermoelectric elements of type N in a direction D. They are in particular of identical shape and dimensions.

Said thermoelectric elements 3p, 3n are for example grouped in pairs, each pair being formed by a said thermoelectric element of type P and by a said thermoelectric element of type N, and said module is configured in order to enable a circulation of current between the first surfaces of the thermoelectric elements of one and the same pair and a circulation of current between the second surfaces of each of the thermoelectric elements of the same pair and the adjacent thermoelectric element of the adjacent pair. This is illustrated in particular in the embodiment of FIG. 1 where the circulation of the electrical current is symbolised by broken lines. In this way it is ensured that the electrical current circulates between the thermoelectric elements 3p, 3n disposed alongside one another in the direction D.

Again, in order to facilitate the configuration of the fluid circulation circuits 1, 2, it may be provided that said thermoelectric elements 3p, 3n are disposed relative to one another in such a way that their first and/or second surfaces 4a, 4b are each in the extension of the other. Thus said first and/or second surfaces 4a, 4b are inscribed for example in a surface generated by a straight line,

For the circulation of the fluids, the module according to the invention could comprise a cold liquid circulation channel 7 in contact with said second surface 4b of said thermoelectric elements 3p, 3n and/or a gas circulation channel 8 in contact with said first surface 4a of said thermoelectric elements 3p, 3n.

The cross-sections of said liquid circulation channel(s) 7 are for example circular. Said gas circulation channel 8 is for example of annular cross-section. Said thermoelectric elements 3p, 3n are disposed between said channels 7, 8, for example radially.

According to the embodiments of FIGS. 1 and 2, on the one hand, and 3a to 3e, on the other hand, said cold liquid circulation channel 7 and said gas circulation channel 8 are coaxial.

In order to further improve the heat exchange between the thermoelectric elements 3p, 3n and the second fluid, the gas circulation channel 8 could be provided with secondary exchange surfaces 9. These are for example radial fins 10. As detailed below, said secondary exchange surfaces could also have other functions, in particular mounting.

In order to protect it and to isolate it from the exterior, the module according to the invention may comprise an external insulating casing 11, optionally defining an external wall of the gas circulation channel 8.

According to the embodiment of FIGS. 1 and 2, the module according to the invention comprises a plurality of tubes 12 each positioned in the axial extension of the other in such a way as to define said cold fluid circulation channel 7. It also comprises a plurality of tubes 13 each positioned in the axial extension of the other so as to define successive portions of an internal wall of said gas circulation channel 8.

The gas circulation tubes 13 are for example coaxial relative to the cold liquid circulation tubes 12 which are placed inside said gas circulation tubes 13 by being axially offset with respect thereto. More precisely, a cold liquid circulation tube 12 is centred here in the direction D between two gas circulation tubes 13.

Each tube 12 of the cold liquid circulation channel 7 is associated with a pair of thermoelectric elements 3p, 3n. The adjacent gas circulation tubes 13, i.e. the tubes 13 inside which said cold liquid circulation tube 12 is placed, are associated with one of said thermoelectric elements 3p, 3n of said tube 12 as well as a respective element 3n, 3p of the adjacent pair of thermoelectric elements 3p, 3n.

Sealing joints 14, 15 could also be provided between said successive cold liquid circulation tubes 12 and/or between said successive gas circulation tubes 13. In addition to their sealing role, they ensure an electrical insulation respectively between said cold liquid circulation tubes 12 and/or between said gas circulation tubes 13.

The said tubes 12, 13 are for example metal. They are coated for example with a fine layer of material, for example ceramic, which ensures thermal conduction and electrical insulation between the tubes and the thermoelectric elements. For the electrical conduction between the thermoelectric elements 3p, 3n, said layer of material may be covered with electrical tracks.

In this embodiment the fins 10 are for example made from the material of the gas circulation tubes 13 which are obtained for example by extrusion.

In this module the cold liquid circulation tubes 12, 13 and/or gas circulation tubes could be provided with shoulders 16, 17 against which the thermoelectric elements 3p, 3n and/or the sealing joints 14, 15 are supported. Said shoulders are provided for example at the longitudinal end of said tubes 12, 13.

The thermoelectric elements 3p, 3n are supported, on one of their planar faces 6a, against the shoulders 17 of the gas circulation tubes 13 in the region of their external periphery and, on their opposing planar face 6b, against the shoulders 16 of the cold liquid circulation tubes in the region of their internal periphery. The joints 14, 15 are placed between two shoulders of respective tubes 12, 13.

By way of example, the mounting of the module is achieved by radial expansion of the cold liquid circulation tubes 12 in such a way as to place said thermoelectric elements 3p, 3n onto the gas circulation tubes 13. As a variant, the mounting of the module is achieved by locking of the gas circulation tubes 13 in such a way as to place said thermoelectric elements 3p, 3n onto the cold liquid circulation tubes 12. A material which ensures a better contact between the thermoelectric elements 3p, 3n and the tubes may also be used.

According to the embodiment of FIGS. 3a to 3e, the module according to the invention comprises a cold liquid circulation tube 12 on which are mounted at least two thermoelectric elements of the same type alternating along the direction of longitudinal extension D of the tube with a thermoelectric element of the other type. In this case, as shown in FIGS. 3b to 3e, a plurality of thermoelectric elements 3p alternates with a plurality of thermoelectric elements 3n.

With reference to FIG. 3a, it will be noted that an electrically insulating washer 20 may be disposed between two faces 6a, 6b facing adjacent thermoelectric elements 3p, 3n in the longitudinal direction of extension D of the tube 12. In FIG. 3b the thermoelectric elements 3p, 3, and the washers 20 are assembled alternately on the cold fluid circulation tube 12.

As illustrated in FIG. 3c, the thermoelectric elements 3p, 3n are for example coated two by two with a layer 22 of electrically conductive material made in particular from copper and/or nickel.

As shown in FIG. 3d, the thermoelectric elements 3p, 3n are also coated with a layer of electrically insulating and thermally conductive material, at least partially defining an internal wall of the gas circulation channel 8. This material is in particular a ceramic material. Said layer 24 of electrically insulating and thermally conductive material is situated above the layer 22 of electrically conductive material.

The cold tube 12 is in particular metal. As in the previous embodiment, it is coated for example with a fine layer of material, for example ceramic, which ensures thermal conduction and electrical insulation between the tube and the thermoelectric elements 3p, 3n. For the electrical conduction between the thermoelectric elements 3p, 3n, said layer of material may be covered with electrical tracks, in particular for the purpose of ensuring a series connection of the thermoelectric elements along the direction D.

As illustrated in FIG. 3e, the secondary exchange surface 9 of this type of module is configured to ensure the retention of the thermoelectric elements 3p, 3n. This is, for example, a metal turbulator 26 exhibiting a radial resilience and adapted to undergo a precompression.

Although this is not shown in relation to the embodiment of FIGS. 3a to 3e, the external periphery of the gas circulation channel 8 is surrounded by a casing of refractory and/or insulating protective material. Said casing may form a support surface for the turbulator 26.

According to the foregoing, the cold liquid circulation channel 7 is unique and placed at the centre of the module.

According to a variant illustrated in FIG. 4, the module comprises a plurality of cold liquid circulation channels 7, parallel to one another, each channel co-operating with a plurality of thermoelectric elements 3 each forming an angular cylinder section and each positioned in the extension of the other along the longitudinal direction of extension of the corresponding channel.

Each channel 7 is defined for example by a tube 12 of cold liquid circulation. There are n cold liquid circulation tubes 12, in this case 4 such tubes, and the thermoelectric elements 3 have the same angular section from one tube to the other, an angle of substantially (360/n) degrees, in this case 90° quadrants of a cylinder, in order to define a cylinder of round cross-section. The cold liquid circulation tubes 12 are for example parallel to one another. In this case they form four edges of a rectangular parallelogram.

The thermoelectric elements 3 are for example of the same thickness and are stacked in successive layers, one layer comprising a thermoelectric element 3 associated with each of the cold liquid circulation tubes 12.

Cross-braces 28 could be provided between each quadrant or equivalent portion in order to separate and hold the thermoelectric elements 3.

For the rest, the module may correspond to that of FIGS. 3a to 3e. Thus it may comprise a protective casing 11.

According to a first embodiment the module of the various preceding embodiments is intended to be used individually.

As illustrated below, they could also form a stick intended to be inserted into a receiving housing of a body of a thermoelectric device.

More broadly, the invention also relates to a device comprising a plurality of modules such as are described above.

As shown in FIG. 5, said device could comprise a body 30 having a plurality of recesses 32 which house said modules 34.

Said body is made for example from refractory, insulating and/or cellular material.

As illustrated in FIGS. 6 and 7, in the case of the above-mentioned stick modules, these later could be inserted in said recesses 32 and held therein, in particular centred, with the aid of the turbulators 26. The external wall of the gas circulation channel 8 could then be defined directly by said body 30. Thus said modules are retained in said recesses 32 by the secondary exchange surfaces 9, in particular due to the radial resilience thereof.

Said recesses 32 are disposed in particular in such a way that the gas circulation channels of the different modules are parallel to one another,

Said body 30 has in particular a substantially cylindrical configuration and the recesses 32 are parallel to one another and parallel to the axis of the body 30. They are for example regularly spaced on the periphery thereof.

From an electrical point of view, the modules could be connected to one another in series and/or in parallel, by connections (not shown) situated at their longitudinal ends.

As a variant, as illustrated in FIG. 7, the device could comprise a gas circulation channel 36 bypassing said modules 34. It is provided in particular in the centre of the body 30.

Said body could again be covered with an external shock-absorbing casing 38.

1. Thermoelectric module comprising at least one thermoelectric element (3, 3p, 3n) which is capable of generating an electric current under the action of a temperature gradient exerted between two of its faces, one (4a), so-called first, of said faces having a greater surface area than the other (4b) so-called second face, said module being configured in order to establish a heat exchange between said first face (4a) and a first fluid and to establish a heat exchange between said second face (4b) and a second fluid, said second fluid having a higher thermal exchange coefficient than said first fluid.

2. Module according to claim 1, wherein the thermoelectric element (3, 3p, 3n) is in the form of a ring or portion of a ring, the first surface (4a) is defined by an external peripheral surface of the ring and the second surface (4b) is defined by an internal peripheral surface of the ring.

3. Module according to any of the preceding claims, wherein said first and/or second surfaces (4a, 4b) are of cylindrical shape.

4. Module according to claim 3, wherein the first surface (4a) has for example a radius between 1.5 and 4 times the radius of the second surface (4b).

5. Module according to any of the preceding claims, wherein said thermoelectric element (3, 3p, 3n) has two opposing parallel planar faces (6a, 6b).

6. Module according to any of the preceding claims, comprising a plurality of said thermoelectric elements (3, 3p, 3n).

7. Module according to claim 6, comprising a cold liquid circulation channel (7) in contact with said second surface (4b) of said thermoelectric elements (3, 3p, 3n) and/or a gas circulation channel (8) in contact with said first surface (4a) of said thermoelectric elements (3, 3p, 3n).

8. Module according to claim 7, wherein the gas circulation channel (8) is provided with secondary exchange surfaces (9).

9. Module according to either claim 7 or claim 8, comprising an external insulating casing (11) defining an external wall of the gas circulation channel (8).

10. Module according to any of claims 7 to 9, comprising a plurality of tubes (12) each positioned in the axial extension of the other in such a way as to define said cold fluid circulation channel (7) and/or a plurality of tubes (13) each positioned in the axial extension of the other so as to be able to define successive portions of an internal wall of said gas circulation channel (8).

11. Module according to claim 10, wherein sealing joints (14, 15) are provided between said successive cold liquid circulation tubes (12) and/or between said successive gas circulation tubes (13), ensuring electrical insulation respectively between said cold liquid circulation tubes (12) and/or between said gas circulation tubes (13).

12. Module according to claim 11, wherein the cold liquid circulation tubes and/or gas circulation tubes (12, 13) are provided with shoulders (16, 17) against which the thermoelectric elements and/or the sealing joints (14, 15) are supported.

13. Module according to any of claims 6 to 8, comprising a cold liquid circulation tube (12) on which are mounted at least two thermoelectric elements (3, 3p, 3n) of the same type alternating along the direction of longitudinal extension with a thermoelectric element of the other type.

14. Module according to claim 12, wherein thermoelectric elements (3, 3p, 3n) are coated with a layer of electrically insulating and thermally conductive material at least partially defining an internal wall of the gas circulation channel (8).

15. Module according to either claim 13 or claim 14, comprising a secondary exchange surface (9), provided in the gas circulation channel (8) and configured in order to ensure the retention of thermoelectric elements (3, 3p, 3n).

16. Module according to any of claims 7 to 9 or 13 to 15, comprising a plurality of cold liquid circulation channels (12), parallel to one another, each channel (12) co-operating with a plurality of thermoelectric elements (3, 3p, 3n) each forming an angular cylinder section and each positioned in the extension of the other along the longitudinal direction of extension of the corresponding channel (12).

17. Thermoelectric device comprising a plurality of modules according to any of claims 7 to 16.

18. Device according to claim 17, comprising a body (30) having a plurality of recesses (32) which house said modules (34).

19. Device according to claim 18, wherein said modules (34) are retained in said recesses (32) by secondary exchange surfaces (9).

20. Device according to either claim 18 or claim 19, wherein said recesses (32) are disposed in particular in such a way that the gas circulation channels (7, 8) of the different modules (34) are parallel to one another.

21. Device according to any of claims 18 to 20, wherein said body (30) is covered with an external shock-absorbing casing (38).

22. Device according to any of claims 17 to 21, comprising a gas circulation channel (36) bypassing said modules (34).
